(19) United States
(12) Patent Application Publication
(10) Pub. No.: US 2019/0181187 A1
(43) Pub. Date: Jun. 13, 2019

(54) PIXEL STRUCTURE AND METHOD FOR MANUFACTURING THE SAME, AND DISPLAY PANEL

(71) Applicants: BOE Technology Group Co., Ltd., Beijing (CN); Hefei Xinsheng Optoelectronics Technology Co., Ltd., Anhui (CN)

(72) Inventors: Jie PAN, Beijing (CN); Shupeng GUO, Beijing (CN); Hu XIE, Beijing (CN); Jun REN, Beijing (CN); Suwei ZENG, Beijing (CN)

(21) Appl. No.: 16/038,257

(22) Filed: Jul. 18, 2018

(30) Foreign Application Priority Data
Dec. 12, 2017 (CN) 201711318531.5

(51) Int. Cl. H01L 27/32; H01L 51/56

(52) U.S. Cl. CPC H01L 27/3211; H01L 51/56; H01L 27/3244

(57) ABSTRACT

The present disclosure discloses a pixel structure and a manufacturing method thereof, and a display panel having the pixel structure. The pixel structure includes a sub-pixel unit, the sub-pixel unit includes a light emitting layer and a light conversion layer disposed on a light emergent side of the light emitting layer, and the light conversion layer includes a Stokes material layer or anti-Stokes material layer. The light conversion layer is used for converting the color of the light emitted by the light emitting layer into an expected color. The pixel structure provided by the present disclosure can improve the utilization efficiency of the light and reduce the energy consumption.

### TECHNICAL FIELD

The present disclosure relates to the field of display technology, and in particular, to a pixel structure and a method for manufacturing the same, and a display panel.

### BACKGROUND ART

An OLED (Organic Light Emitting Diode) is expected as a new-generation display device. In the existing OLED display device, a technical solution in which a white light OLED is used in combination with a color filter to emit light of different colors is generally adopted, and the solution has an advantage of high resolution.

However, since the most of the light is absorbed by the color filter, the overall energy consumption of the OLED display device is high. Therefore, how to obtain an OLED display device with high resolution and low power consumption is an urgent problem to be solved.

### SUMMARY

The present disclosure proposes a pixel structure and a method for manufacturing the same, and a display panel comprising the pixel structure.

The present disclosure provides a pixel structure, including a sub-pixel unit, wherein the sub-pixel unit includes a light emitting layer and a light conversion layer disposed on a light emergent side of the light emitting layer, and the light conversion layer includes a Stokes material layer or anti-Stokes material layer.

Optionally, the light conversion layer includes a Stokes material layer capable of converting the light emitted by the light emitting layer into red light.

Optionally, the light conversion layer includes an anti-Stokes material layer capable of converting the light emitted by the light emitting layer into green light.

Optionally, the light emitted by the light emitting layer is yellow light.

Optionally, the Stokes material layer or the anti-Stokes material layer includes a matrix made of a metal oxide, a metal fluoride or a metal sulfide, and metal activation particles doped in the matrix.

Optionally, for the Stokes material layer, the matrix includes sodium fluoride; and the metal activation particles is one or more selected from trivalent yttrium ion, trivalent ytterbium ion and trivalent cerium ion.

Optionally, for the anti-Stokes material layer, the matrix includes sodium fluoride, and the metal activation particles is one or more selected from trivalent yttrium ion, trivalent ytterbium ion and trivalent holmium ion.

Optionally, a plurality of sub-pixel units are disposed, and the light conversion layer is disposed on the light emergent side of the light emitting layer in at least one sub-pixel unit, so that the colors of the plurality of sub-pixel units are different.

Optionally, three sub-pixel units of a blue sub-pixel, a red sub-pixel and a green sub-pixel are disposed; wherein

the light emitting layer of the blue sub-pixel emits blue light;

the light emitting layers of the red sub-pixel and the green sub-pixel both emit yellow light;

the light conversion layer includes a first light conversion layer and a second light conversion layer, wherein the first light conversion layer is disposed on the light emergent side of the light emitting layer of the red sub-pixel, and the first light conversion layer includes a Stokes material layer capable of converting yellow light into red light; and the second light conversion layer is disposed on the light emergent side of the light emitting layer of the green sub-pixel, and the second light converting layer includes an anti-Stokes material layer capable of converting the yellow light into green light.

The present disclosure further provides a method for manufacturing a pixel structure, comprising:

forming a light emitting layer of a sub-pixel unit of the pixel structure; and

forming a light conversion layer on the light emergent side of the light emitting layer, wherein the light conversion layer comprises a Stokes material layer and/or an anti-Stokes material layer.

Optionally, in the method for manufacturing a pixel structure according to the present disclosure, the light conversion layer comprises a Stokes material layer capable of converting the light emitted by the light emitting layer into red light.

Optionally, in the method for manufacturing a pixel structure according to the present disclosure, the light emitted by the light emitting layer is yellow light, and the light conversion layer comprises a Stokes material layer capable of converting the yellow light into red light;

forming the red light Stokes material layer comprises:

providing a matrix made of sodium fluoride;

doping metal activation particles in the matrix, wherein the metal activation particles are selected from one or more of trivalent yttrium ions, trivalent ytterbium ions and trivalent cerium ions; and

sintering the matrix doped with the metal activation particles by using glutamic acid as a sintering agent to form the Stokes material layer.

Optionally, in the method for manufacturing a pixel structure according to the present disclosure, the light conversion layer comprises an anti-Stokes material layer capable of converting the light emitted by the light emitting layer into green light.

Optionally, in the method for manufacturing a pixel structure according to the present disclosure, the light emitted by the light emitting layer is yellow light, and the light conversion layer comprises an anti-Stokes material layer capable of converting the yellow light into green light;

forming the anti-Stokes material layer comprises:

providing a matrix made of sodium fluoride;

doping metal activation particles in the matrix, wherein the metal activation particles are selected from one or more of trivalent yttrium ions, trivalent ytterbium ions and trivalent holmium ions; and

sintering the matrix doped with the metal activation particles by using citric acid as a sintering agent to form the anti-Stokes material layer.

Optionally, the method for manufacturing the pixel structure according to the present disclosure further comprises a step of forming a yellow light adjustment layer when the light emitted by the light emitting layer is yellow light.

As another technical solution, the present disclosure further provides a display panel, including a plurality of pixel structures provided by the present disclosure.

### BRIEF DESCRIPTION OF THE DRAWINGS

FIG. 1 is a schematic diagram of a pixel structure according to the present disclosure;

FIG. 2 is a schematic diagram of another pixel structure according to the present disclosure;

FIG. 3A is a schematic diagram of yet another pixel structure according to the present disclosure;

FIG. 3B is a light emitting principle diagram of the pixel structure as shown in FIG. 3A;

FIG. 4 is a detailed schematic diagram of the pixel structure as shown in FIG. 3A.

### DETAILED DESCRIPTION OF THE EMBODIMENTS

In order that those skilled in the art can better understand the technical solutions of the present disclosure, a pixel structure and a manufacturing method thereof, and a display panel having the pixel structure provided by the present disclosure are described in detail below in combination with the drawings.

The pixel structure provided by the present disclosure is used as a pixel unit of a display panel, and it includes a sub-pixel unit including a light emitting layer and a light conversion layer disposed on a light emergent side of the light emitting layer, wherein the light conversion layer includes a Stokes Material layer or an anti-Stokes material layer.

The above-mentioned light emitting layer is self-luminous material, for example, it may be an organic light emitting material layer.

The Stokes material layer and the anti-Stokes material layer made of light conversion materials are named according to the Stokes Effect. The Stokes Effect means that an emitting light of a material has a greater wavelength than that of an exciting light. In the present disclosure, the term “Stokes material layer” refers to a layer capable of emitting low-energy light (having greater wavelength) when being excited by high-energy light; and the term “anti-Stokes material layer” refers to a layer capable emitting high-energy light (having shorter wavelength) when being excited by low-energy light. Based on this, the Stokes material layer and the anti-Stokes material layer could realize conversion of light, i.e. converting the light emitted by the light emitting layer into light having a desired color. As a benefit, the Stokes material layer and the anti-Stokes material layer do not cause loss of light energy, thereby improving the utilization efficiency of the light and reducing the energy consumption.

Depending on the different colors of the light emitted by the light emitting layer, such as green light, red light, white light or blue light, different light conversion layers could be selected as long as the light having desired color could be obtained.

Hereinafter, taking a light emitting layer emitting yellow light as an instance, a specific embodiment of the sub-pixel unit according to the present disclosure will be described, but the present disclosure is not limited thereto.

As for a red sub-pixel, it is desired that the light conversion layer could convert the yellow light emitted by the light emitting layer into red light. As shown in FIG. 1, the light emitting layer 31 and the light conversion layer 41 are located between a backboard 1 and a cover plate 2 of the pixel unit, and the light conversion layer 41 is disposed on the light emergent side of the light emitting layer 31. The light emitted by the light emitting layer 31 is yellow light Y, and the light conversion layer 41 includes a Stokes material layer capable of converting the yellow light into red light R.

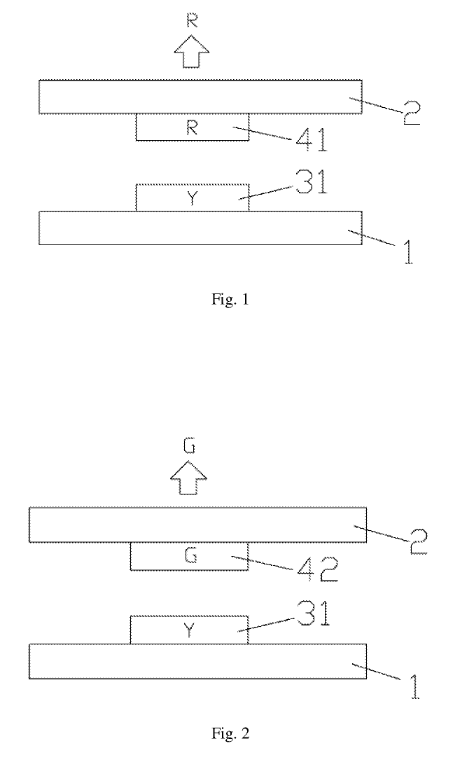

The wavelength of yellow light is generally 577 nm to 597 nm; and the wavelength of red light is generally 620 nm to 780 nm. Compared with red light, yellow light has higher energy. The Stokes material layer can emit low-energy red light when being excited by the high-energy yellow light. As for a green sub-pixel, it is desired that the light conversion layer could convert the yellow light emitted by the light emitting layer into green light. As shown in FIG. 2, the light emitting layer 31 and the light conversion layer 42 are located between the backboard 1 and the cover plate 2, and the light conversion layer 42 is disposed on the light emergent side of the light emitting layer 31. The light emitted by the light emitting layer 31 is yellow light Y, and the light conversion layer 42 includes an anti-Stokes material layer capable of converting the yellow light into the green light G.

The wavelength of green light is generally from 520 nm to 580 nm. Compared with green light, yellow light has lower energy. The anti-Stokes material layer emits high-energy green light when being excited by the low-energy yellow light.

The Stokes material layer or the anti-Stokes material layer typically includes a matrix made of a metal oxide, a metal fluoride or a metal sulfide, and the matrix is doped with metal activation particles. For example, the metal activation particles may be rare earth light emitting particles.

The above-mentioned Stokes material layer for converting yellow light into red light may include a matrix made of sodium fluoride, and one or more kinds of metal activation particles selected from trivalent yttrium ion (Y³⁺), trivalent ytterbium ion (Yb³⁺) and trivalent cerium ion (Ce³⁺).

The above-mentioned anti-Stokes material layer for converting yellow light into green light may include a matrix made of sodium fluoride, and one or more kinds of metal activation particles selected from trivalent yttrium ion (Y³⁺), trivalent ytterbium ion (Yb³⁺) and trivalent holmium ion (Ho³⁺).

According to other embodiments of the present disclosure, the pixel structure is substantially the same as the pixel structure provided by the above-mentioned embodiment, except that it has different numbers of sub-pixel units and different light conversion layers.

A plurality of sub-pixel units can be disposed, and the light conversion layer is disposed on the light emergent side of the light emitting layer in at least one sub-pixel unit, so that the colors of the plurality of the sub-pixel units are different.

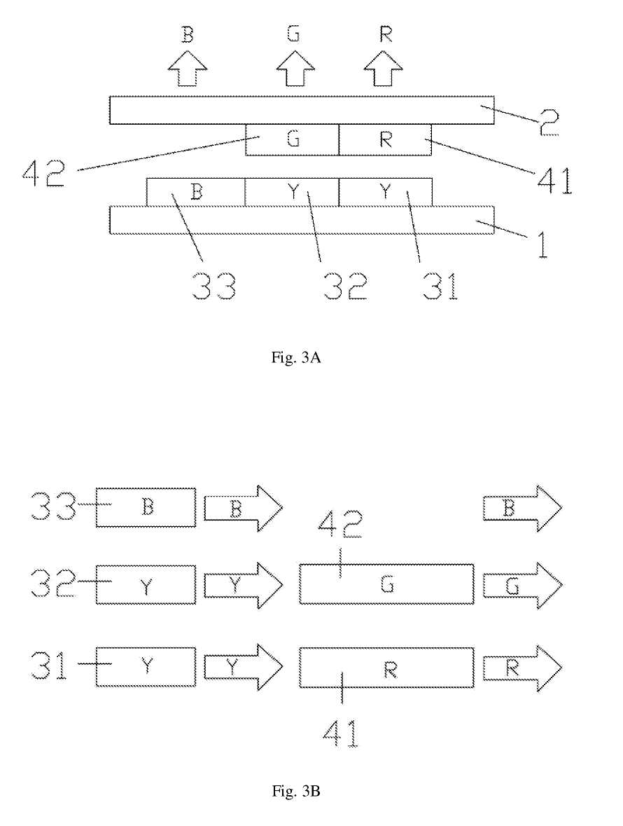

For example, referring to FIGS. 3A and 3B, the pixel structure includes three sub-pixels, i.e. a blue sub-pixel, a red sub-pixel and a green sub-pixel; wherein the light emitting layer 33 of the blue sub-pixel is a light emitting layer emitting blue light B; the light emitting layer 31 of the red sub-pixel and the light emitting layer 32 of the green sub-pixel are both light emitting layers emitting yellow light Y; the light conversion layers include a first light conversion layer 41 and a second light conversion layer 42, wherein the first light conversion layer 41 is disposed on the light emergent side of the light emitting layer 31 of the red sub-pixel, and the first light conversion layer 41 is a Stokes material layer capable of converting yellow light Y into red light R; the second light conversion layer 42 is disposed on the light emergent side of the light emitting layer 32 of the green sub-pixel, and the second light conversion layer 42 is an anti-Stokes material layer capable of converting yellow light Y into green light G.

Since the light emitted by the light emitting layers are converted into light having an desired color by using the Stokes material layer and the anti-Stokes material layer in the pixel structure according to the present disclosure, compared with the prior art using white light OLED and the color filter, the pixel structure of the present disclosure has substantially no loss of light energy, thereby improving the utilization efficiency of the light and reducing the structural energy consumption.

In addition, since the light emitting layer 31 of the red sub-pixel and the light emitting layer 32 of the green sub-pixel are both light emitting layers emitting yellow light, the light emitting layers of the two sub-pixels can be simultaneously formed in manufacturing a pixel structure, thereby reducing the times of using a fine mask and the times of performing high-precision alignment (aligning the mask with the substrate). As a result, the risk of color mixing is reduced, and the yield is improved. In addition, the light emitting layer 31 and light emitting layer 32 can also be made into an integrated structure, which can increase the area of the sub-pixel unit, so that the fine mask is easier to manufacture.

Specific embodiments of the pixel structure according to the present disclosure are described below.

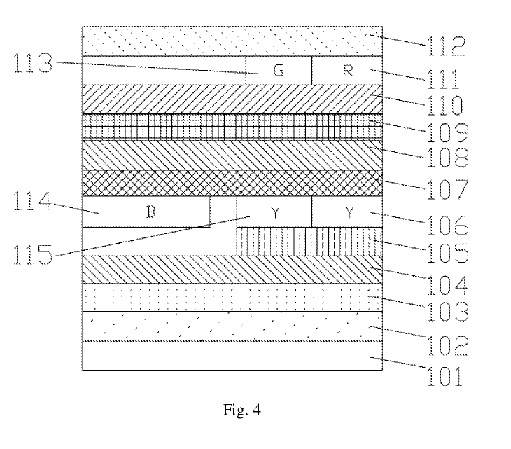

Referring to FIG. 4, the pixel structure includes a backboard 101, an anode layer 102 disposed on the backboard 101, a cathode layer 109, light emitting functional layers disposed between the anode layer 102 and the cathode layer 109, an optical coupling layer 110 disposed on the cathode layer 109, and a cover plate 112 disposed on the optical coupling layer 110, wherein the light emitting function layers includes a hole injection layer 103, a hole transport layer 104, an electron transport layer 107 and an electron injection layer 108 which are successively disposed between the anode layer 102 and the cathode layer 109.

The light emitting layer of the sub-pixel unit is disposed between the hole transport layer and the electron transport layer. The sub-pixel units are respectively a blue sub-pixel, a red sub-pixel and a green sub-pixel, and the light emitting layers (114, 106, 115) of the three sub-pixel units are disposed in parallel between the hole transport layer 103 and the electron transport layer 107. The light emitted by the light emitting layer 106 of the red sub-pixel and the light emitting layer 115 of the green sub-pixel is yellow light, and a yellow light adjustment layer 105 is disposed between the light emitting layers 106 and 115 of the red sub-pixel and the green sub-pixel and the hole transport layer 104. The yellow light adjustment layer 105 functions to adjust the half-wave width of the yellow light and improve the light emitting efficiency.

The first light conversion layer 111 and the second light conversion layer 113 are disposed between the optical coupling layer 110 and the cover plate 112, and are located at the positions corresponding to the light emitting layers 106 and 115. The first light conversion layer 111 is a Stokes material layer capable of converting the yellow light emitted by the light emitting layer 106 into red light; and the second light conversion layer 113 is an anti-Stokes material layer capable of converting the yellow light emitted by the light emitting layer 115 into green light.

The light conversion layer not only can be disposed between the optical coupling layer 110 and the cover plate 112, but also can be disposed in the cover plate 112, or disposed at (for example) any other position on a package layer, as long as the color conversion of the light emitted by the light emitting layer can be achieved.

It should be understood that the pixel structure is not limited to including the above-mentioned various functional layers. In practical application, the corresponding functional layers can be increased or decreased according to specific needs.

The present disclosure further provides a method for manufacturing a pixel structure, including:

forming a light emitting layer of a sub-pixel unit of the pixel structure; and

forming a light conversion layer on the light emergent side of the light emitting layer,

wherein the light conversion layer includes a Stokes material layer and/or an anti-Stokes material layer.

The Stokes material layer is capable of converting the light emitted by the light emitting layer into red light.

For example, when the light emitted by the light emitting layer is yellow light, the light conversion layer includes a Stokes material layer capable of converting the yellow light into red light.

Forming the Stokes material layer capable of converting the yellow light into red light includes:

providing a matrix made of sodium fluoride;

doping metal activation particles in the matrix, wherein the metal activation particles are one or more selected from trivalent yttrium ions, trivalent ytterbium ions and trivalent cerium ions; and

sintering the matrix doped with the metal activation particles by using glutamic acid as a sintering agent to form the Stokes material layer.

The anti-Stokes material layer is capable of converting the light emitted by the light emitting layer into green light.

For example, when the light emitted by the light emitting layer is yellow light, and the light conversion layer includes an anti-Stokes material layer capable of converting the yellow light into green light;

Forming the anti-Stokes material layer capable of converting the yellow light into green light includes:

providing a matrix made of sodium fluoride;

doping metal activation particles in the matrix, wherein the metal activation particles are one or more selected from trivalent yttrium ions, trivalent ytterbium ions and trivalent holmium ions; and

sintering the matrix doped with the metal activation particles by using citric acid as a sintering agent to form the anti-Stokes material layer.

The materials and processes described above for forming the Stokes layer and the anti-Stokes layer are for illustrative purposes only, rather than limiting the present disclosure. Those skilled in the art can select the materials and processes for forming the Stokes layer and the anti-Stokes layer according to demands (e.g., the color of the light emitted by the light emitting layer, and the color of the light to be converted into).

The method for manufacturing the pixel structure according to the present disclosure further comprises a step of forming a yellow light adjustment layer. The yellow light adjustment layer can be formed according to any known method in the art by a person skilled in the art.

By adoption of the method for manufacturing the pixel structure provided by the present disclosure, the color of light emitted by the light emitting layer not only can be converted into the expected color, but also causes no loss of light energy, thereby improving the utilization efficiency of the light and reducing the structural energy consumption.

The present disclosure further provides a display panel, including a plurality of pixel structures, wherein the pixel structure employs the above-mentioned pixel structure provided by the present disclosure.

The display panel of the present disclosure is suitable for various display devices. The display device may be any product or component having a display function, such as a liquid crystal display, electronic paper, a mobile phone, a tablet computer, a television, a display, a notebook computer, a digital photo frame, a navigator, or the like.

By adoption of the pixel structure provided by the present disclosure, the display panel provided by the present disclosure not only can convert the color of the light emitted by the light emitting layer into the expected color, but also causes no loss of light energy, thereby improving the utilization efficiency of the light and reducing the structural energy consumption.

It can be understood that the above embodiments are merely exemplary embodiments used for explaining the principles of the present disclosure, but the present disclosure is not limited thereto. For those of ordinary skill in the art, various modifications and improvements can be made without departing from the spirit and scope of the disclosure, and these modifications and improvements are also encompassed within the protection scope of the present disclosure.

1. A pixel structure, comprising
a sub-pixel unit, wherein the sub-pixel unit comprises
a light emitting layer, and
a light conversion layer disposed on a light emergent side of the light emitting layer, and the light conversion layer comprises a Stokes material layer and/or anti-Stokes material layer.

2. The pixel structure according to claim 1, wherein the light conversion layer comprises a Stokes material layer capable of converting the light emitted by the light emitting layer into red light.

3. The pixel structure according to claim 1, wherein the light conversion layer comprises an anti-Stokes material layer capable of converting the light emitted by the light emitting layer into green light.

4. The pixel structure according to claim 1, wherein the light emitting layer emits yellow light and the sub-pixel unit further comprises a yellow light adjustment layer.

5. The pixel structure according to claim 2, wherein the Stokes material layer comprises a matrix made of a metal oxide, a metal fluoride or a metal sulfide, and metal activation particles doped in the matrix.

6. The pixel structure according to claim 3, wherein the anti-Stokes material layer comprises a matrix made of a metal oxide, a metal fluoride or a metal sulfide, and metal activation particles doped in the matrix.

7. The pixel structure according to claim 4, wherein for the Stokes material layer, the matrix comprises sodium fluoride; and the metal activation particles are one or more selected from trivalent yttrium ion, trivalent ytterbium ion and trivalent cerium ion.

8. The pixel structure according to claim 4, wherein for the anti-Stokes material layer, the matrix comprises sodium fluoride, and the metal activation particles are one or more selected from trivalent yttrium ion, trivalent ytterbium ion and trivalent holmium ion.

9. The pixel structure according to claim 1, wherein a plurality of sub-pixel units are disposed, and at least one sub-pixel unit comprises the light conversion layer, so that the colors of the plurality of the sub-pixel units are different.

10. The pixel structure according to claim 9, wherein three sub-pixel units are disposed, which are respectively a blue sub-pixel, a red sub-pixel and a green sub-pixel; wherein
the light emitted by the light emitting layer of the blue sub-pixel is blue light;
the light emitted by the light emitting layers of the red sub-pixel and the green sub-pixel is yellow light;
the light conversion layers comprise a first light conversion layer and a second light conversion layer, wherein the first light conversion layer is disposed on the light emergent side of the light emitting layer of the red sub-pixel, and the first light conversion layer comprises a Stokes material layer capable of converting yellow light into red light; and the second light conversion layer is disposed on the light emergent side of the light emitting layer of the green sub-pixel, and the second light converting layer comprises an anti-Stokes material layer capable of converting the yellow light into green light.

11. A method for manufacturing a pixel structure, comprising:
forming a light emitting layer of a sub-pixel unit of the pixel structure; and
forming a light conversion layer on the light emergent side of the light emitting layer, wherein the light conversion layer comprises a Stokes material layer and/or an anti-Stokes material layer.

12. The method for manufacturing the pixel structure according to claim 11, wherein the light conversion layer comprises a Stokes material layer capable of converting the light emitted by the light emitting layer into red light.

13. The method for manufacturing the pixel structure according to claim 12, wherein the light emitted by the light emitting layer is yellow light, and the light conversion layer comprises a Stokes material layer capable of converting the yellow light into red light;
forming the red light Stokes material layer comprises:
providing a matrix made of sodium fluoride;
doping metal activation particles in the matrix, wherein the metal activation particles are selected from one or more of trivalent yttrium ions, trivalent ytterbium ions and trivalent cerium ions; and
sintering the matrix doped with the metal activation particles by using glutamic acid as a sintering agent to form the Stokes material layer.

14. The method for manufacturing the pixel structure according to claim 13, wherein the method further comprises a step of forming a yellow light adjustment layer.

15. The method for manufacturing the pixel structure according to claim 11, wherein the light conversion layer comprises an anti-Stokes material layer capable of converting the light emitted by the light emitting layer into green light.

16. The method for manufacturing the pixel structure according to claim 15, wherein the light emitted by the light emitting layer is yellow light, and the light conversion layer comprises an anti-Stokes material layer capable of converting the yellow light into green light;
forming the anti-Stokes material layer comprises:
providing a matrix made of sodium fluoride;
doping metal activation particles in the matrix, wherein the metal activation particles are selected from one or more of trivalent yttrium ions, trivalent ytterbium ions and trivalent holmium ions; and
sintering the matrix doped with the metal activation particles by using citric acid as a sintering agent to form the anti-Stokes material layer.

17. The method for manufacturing the pixel structure according to claim 16, wherein the method further comprises a step of forming a yellow light adjustment layer.

18. A display panel, comprising a plurality of pixel structures, wherein the pixel structure is the pixel structure according to claim 1.
